(19) United States
(12) Patent Application Publication
(10) Pub. No.: US 2023/0369279 A1
(43) Pub. Date: Nov. 16, 2023

(54) METHOD OF MANUFACTURING SEMICONDUCTOR DEVICES AND CORRESPONDING SEMICONDUCTOR DEVICE

(71) Applicant: STMicroelectronics S.r.l., grate Brianza (MB) (IT)

(72) Inventors: Thomas GOTTARDI, Muggio (IT); Nicoletta MODARELLI, Milano (IT); Guendalina CATALANO, Milano (IT)

(73) Assignee: STMicroelectronics S.r.l., Agrate Brianza (MB) (IT)

(21) Appl. No.: 18/144,347

(22) Filed: May 8, 2023

(30) Foreign Application Priority Data
May 12, 2022 (IT) 102022000009839

(51) Int. Cl. H01L 23/00; H01L 23/495

(52) U.S. Cl. CPC H01L 24/40; H01L 23/49582; H01L 24/32; H01L 24/37; H01L 24/73; H01L 24/83; H01L 24/84; H01L 24/92; H01L 23/49513; H01L 2224/32245; H01L 2224/37013; H01L 2224/40245; H01L 2224/40499; H01L 2224/73263; H01L 2224/83192; H01L 2224/83801; H01L 2224/84801; H01L 2224/92246; H01L 2924/01029; H01L 2924/01047

(57) ABSTRACT

A semiconductor die is attached on a die-attachment portion of a planar substrate. A planar electrically conductive clip in mounted onto the semiconductor die. The semiconductor die is sandwiched between the die-attachment portion and the electrically conductive clip. A distal portion of the electrically conductive clip extending away from the semiconductor die is spaced from an electrically conductive lead of the planar substrate by a gap. This gap is filled by a mass of gap-filling material transferred to an upper surface of the electrically conductive lead via Laser Induced Forward Transfer (LIFT) processing. A mass of the gap-filling material is sized and dimensioned to substantially fill the gap.

### PRIORITY CLAIM

This application claims the priority benefit of Italian Application for Patent No. 102022000009839 filed on May 12, 2022, the content of which is hereby incorporated by reference in its entirety to the maximum extent allowable by law.

### TECHNICAL FIELD

The description relates to manufacturing semiconductor devices.

The description refers, by way of example, to manufacturing dual-side cooling packages for semiconductor devices.

### BACKGROUND

A dual-side cooling package for a semiconductor power device currently comprises a leadframe as substrate and one or more semiconductor chips or dice sandwiched between the substrate and one or more flat clips (wherein flat means that the clip does not include any bends or bent portions; i.e., the clip is essential a planar body).

The assembly thus created includes a gap due to the die thickness (70 microns, for instance) formed between mutually facing (distal) portions of the substrate and the flat clip(s).

Such a gap could be attempted to be accommodated by machining the clip material (via milling or extrusion, for example) which may be expensive.

Another approach may involve clip tip bending (such as by providing a bend with a corresponding bent portion to account for the die thickness gap); this is hardly practicable due to clip thickness (more than 600 microns).

Still another approach may involve using leadframes with dual lead levels or leadframes produced in two different parts that are subsequently connected: this is again fairly expensive. In any case, dedicated leadframes and/or clips may reduce the time-to-market and increase the final cost a product.

Mounting a stand-off/spacer (a thin copper foil, for instance) using solder paste or glue can also be considered. Such an approach is difficult to implement since the resulting assembly is exposed to a (first) oven reflow for die attachment before clip mounting. The temperature increase resulting from reflow tends to cause undesired spacer bending/lift-off.

There is accordingly a need in the art to address the issues discussed in the foregoing.

### SUMMARY

One or more embodiments may relate to a method.

One or more embodiments also relate to a corresponding semiconductor device.

In solutions as described herein, a spacer (for example, copper) is formed via Laser Induced Forward Transfer (LIFT) processing on the lead side to compensate for the die thickness.

LIFT processing can accommodate a high die thickness in a direct-write approach, for instance.

The related process can be easily tuned to different die thicknesses without having to manage different clip or leadframe references.

LIFT processing has been found to be largely advantageous over other “printing” processes within the context of use considered herein.

Solutions as presented herein offer one or more of the following advantages: adaptability (“customization”) to different types of power packages; applicability to leadframes and clips having a single thickness (“mono-thickness”); cost savings (only a leadframe preparation step may be added); capability of covering a variety of products/packages with a simple; and single assembly step with no appreciable effect on the rest of the assembly flow.

### BRIEF DESCRIPTION OF THE DRAWINGS

One or more embodiments will now be described, by way of example only, with reference to the annexed figures, wherein:

FIG. 1 is a cross-sectional view of a semiconductor power device suited to be manufactured with embodiments of the present description,

FIGS. 2A, 2B and 2C are exemplary of steps in a Laser Induced Forward Transfer (LIFT) process, and

FIGS. 3A to 3F are exemplary of possible steps in implementing embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description: like parts or elements are indicated in the various figures with like reference signs, and a corresponding description will not be repeated for each and every figure; and manufacturing a single device will be described, being otherwise understood that current manufacturing processes of semiconductor devices involve manufacturing concurrently plural devices that are separated into single individual devices in a final singulation step.

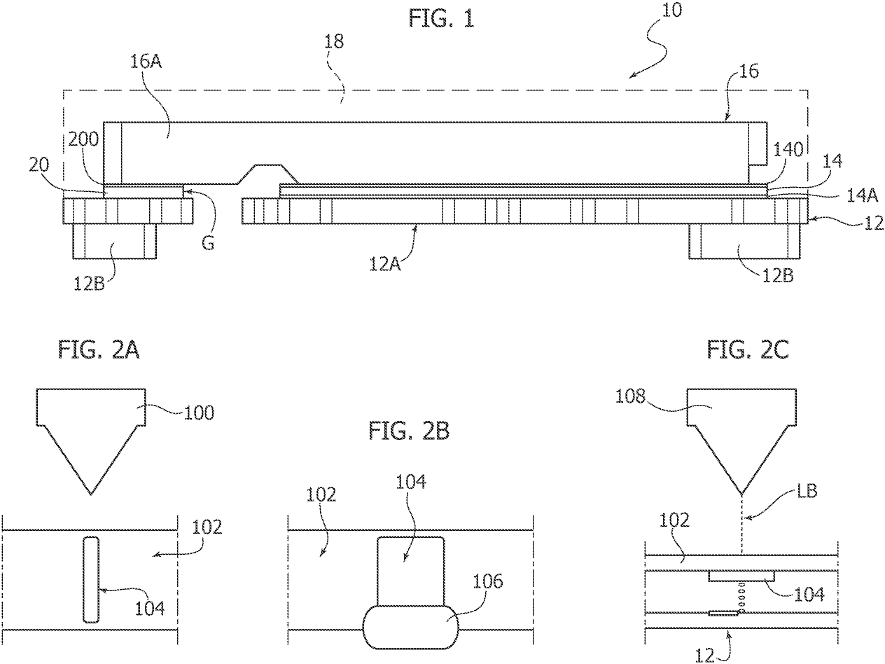

FIG. 1 is a cross-sectional view through a semiconductor (power) device 10 that comprises - in a manner known per se to those of skill in the art: a metal substrate (leadframe) 12 in turn comprising a die-mounting area (die pad) 12A onto which one or more semiconductor integrated circuit chips or dice 14 are mounted via a solder paste layer (not visible due to scale reasons); and one or more flat metal clips 16 in turn arranged onto the chip or chips 14 to provide an electrical connection between the chip or chips 14 and a set of electrically conductive “distal” leads 12B (on the left-hand side of the figure) of the leadframe 12.

Other leads 12B associated with the die-mounting portion 12A of the leadframe 12 are visible on the right-hand side of FIG. 1. It will be noted that the upper surfaces of the die-mounting portion 12A and the set of electrically conductive “distal” leads 12B of the leadframe 12 are coplanar.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the chip or die to other electrical components or contacts.

Essentially, a leadframe comprises an array of electrically conductive formations (or leads, for example, 12B) that from an outline location extend inwardly in the direction of a semiconductor chip or die (for example, 14) thus forming an array of electrically conductive formations from a die pad (for example, 12A) configured to have – at least one – semiconductor integrated circuit chip or die attached thereon.

For the sake of simplicity, a single chip or die 14 and a single flat clip 16 will be referred to throughout this description, being otherwise understood that solutions as discussed herein also apply to arrangements including plural semiconductor chips or dice 14 and/or plural clips 16.

An encapsulation of insulating material 18 (an epoxy resin, for instance: the outline of the material 18 is illustrated in dashes lines in FIG. 1) is molded onto the assembly thus described, leaving the leads 12B accessible. A case is thus provided that surrounds the semiconductor material to protect it from corrosion or physical damage while facilitating mounting the device onto a mounting substrate such as a Printed Circuit Board (PCB) not visible in the figures).

Observation of FIG. 1 shows that, due to a thickness of the die 14, a gap G is formed between the “distal” end of the clip 14 and the leads 12B arranged facing that distal end of the clip 16.

Just by way of reference (and with no limitative intent) the leadframe 12B may have a thickness of 500 microns and the die 14 may in turn have a thickness of 70 micron, to which the thicknesses of the die attach material used to attach the die 14 onto the leadframe 12.

Consequently, the gap G may have a thickness (width in the vertical direction of FIG. 1) of about 70 + 25 microns. This quantitative figure is, of course, merely exemplary and not limiting of the embodiments.

As discussed, a gap as indicated by G (between the upper surface of the leads 12B and the bottom surface of the clip 16) could be attempted to be compensated (bridged) by resorting to different approaches (clip material milling/extrusion, clip bending, leadframes with dual lead levels or including two different elements connected).

These approaches exhibit various types of disadvantages.

For instance, in the case of clip material milling, a fairly large amounts of clip materials may have to be removed, possibly respecting fairly tight tolerances in terms of thickness and planarity. Additionally, this may be a fairly expensive solution.

Clip bending may involve risks of cracking (the die or dice 14) due to the thickness of the clip material 16 (for example, 650 microns).

Resorting to leadframes with dual lead levels or including separate elements is generally expensive and may involve additional assembly steps.

Solutions as discussed herein address the problem of compensating (bridging) a gap, such as the gap G, while supporting the use of a flat (planar) clip and coplanar upper surfaces of the die-mounting portion 12A and the set of electrically conductive “distal” leads 12B of the leadframe 12, by growing electrically conductive material and resorting to Laser-Induced Forward Transfer (LIFT) technology.

The acronym LIFT denotes a deposition process where material from a donor tape or sheet is transferred to an acceptor substrate facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

Essentially, solutions as discussed herein contemplate (filling or bridging) the gap G via a mass 20 of electrically conductive material transferred via LIFT processing onto the leads 12A facing the distal end of the flat clip 16.

It is noted that, in comparison with other “printing” processes that could be notionally envisaged to fill the gap G, LIFT processing facilitates providing a “customized” connection between the back or bottom side of the flat clip 16 and the leads 12A in leadframe 12.

Advantageously, LIFT processing facilitates adapting the thickness of the material transferred via LIFT processing (typically in subsequent layers) to the width of the gap G by adapting precisely to possible variations thereof, for example, variations in die thickness for various dice in a batch.

FIGS. 2A, 2B and 2C are exemplary of possible implementations of LIFT processing that are advantageously configured for use in a context as considered herein.

In FIG. 2A, reference 100 indicates a paste dispenser head configured to deposit on a donor film 102 an electrically conductive paste 104 (an Ag/Cu paste, for instance).

FIG. 2B is exemplary of the possibility of spreading the paste 104 to a desired width (and thickness) via a laminator 106 (essentially a doctor blade).

As exemplified in FIG. 2C, a laser beam LB from a laser source 108 can then be used to transfer the paste 104 from the donor film 102 onto a substrate such as, for instance, the upper surface of the leadframe 12 (at the leads 12B located at the gap G).

Essentially, the action of the laser source 108 (a UV laser, for instance) is to “shoot” a laser beam LB onto the back side of the donor tape 102, so that the paste 104 that is spread on the front side of the donor tape 102 is projected and dispensed (in an ultra-fast mode) onto the upper surface of the substrate 12 to provide - in one or more steps - the “gap-bridging” material 20.

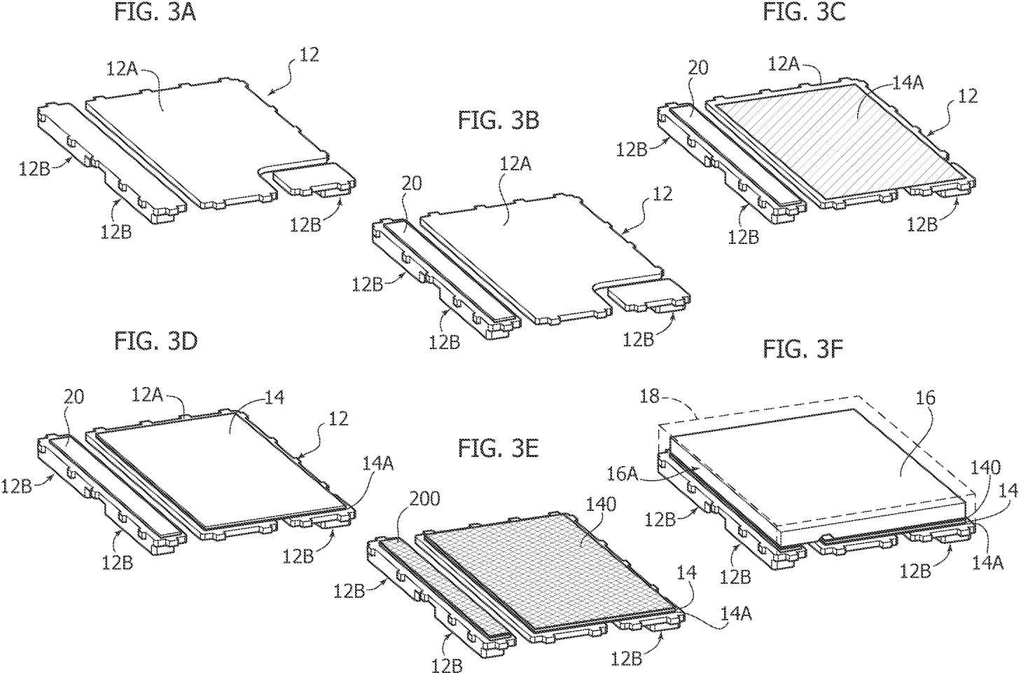

FIGS. 3A to 3F are illustrative of a possible sequence of steps in implementing a solution as discussed herein.

It will be otherwise appreciated that the sequence of steps of FIGS. 3A to 3F is merely exemplary insofar as: one or more steps illustrated in FIGS. 3A to 3F can be omitted, performed in a different manner (with other tools, for instance) and/or replaced by other steps; additional steps may be added; and one or more steps can be carried out in a sequence different from the sequence illustrated.

FIG. 3A is exemplary of the provision of a leadframe 12, including a die-mounting portion (die pad) 12A and electrically conductive leads, including “distal” leads (on the left-end side of the Figure) where a gap G may be formed for the reasons discussed in the foregoing.

FIG. 3B is exemplary of the deposition (via LIFT processing) onto the “distal” leads 12B of the leadframe 12 of one or more layers of material (copper, for instance) up to a resulting thickness corresponding to the thickness of the gap G to be bridged.

This thickness is known beforehand since the thickness of the die 14 (and the die attach material of the die 14 onto the die pad 12A of the leadframe 12) are known as process parameters. It will be otherwise noted that solutions as discussed herein may adapt to different thicknesses of the die 14 (and the die attach material) in a very flexible way.

FIG. 3C is exemplary of the deposition of such die attach layer 14A (of a solder paste, for instance) to facilitate die attachment as illustrated in FIG. 3D.

FIG. 3E is exemplary of material such as solder paste being dispensed onto the upper surface of the chip 14 (solder paste 140) and onto the upper surface of the LIFT deposited layer or layers 20 (solder paste material 200) in order to facilitate attaching the flat clip or clips 16, as exemplified in FIG. 3F.

It will be noted, from FIG. 1, that the flat clip 16 includes, at its bottom surface, notch between a portion of the back surface where attachment is made to the chip 14 and a portion of the back surface where attachment is made to the layer 20. When mounting the clip 16, this notch is aligned with the peripheral edge of the chip 14.

It is noted that the solder paste layers 140 and 200 may have a same thickness and thus may not play a major role in compensating for the gap G.

As exemplified in dashed lines in FIG. 3F an insulating encapsulation 18 can then be formed on the resulting assembly as otherwise conventional in the art.

As noted, steps illustrated in FIGS. 3A to 3F can be carried out in a sequence different from the sequence illustrated.

For instance, LIFT deposition of the material 20 onto the “distal” leads 12B of the leadframe 12 can be (as shown) prior to mounting the chip 14 on the leadframe 12, after mounting the chip 14 on the leadframe 12, or concurrent with mounting the chip 14 on the leadframe 12.

Deposition of the material 20 (copper, for instance) via LIFT processing may be in one or more layers up to a resulting thickness corresponding to the thickness of the gap G to be bridged.

Solutions as discussed herein may adapt to different thicknesses of the die 14 (and the die attach material) in a very flexible way.

Without prejudice to the underlying principles, the details and embodiments may vary, even significantly, with respect to what has been described by way of example only without departing from the extent of protection.

The claims are an integral part of the technical teaching provided herein in respect of the embodiments.

The extent of protection is determined by the annexed claims.

1. A method, comprising:
attaching a semiconductor integrated circuit die to an upper surface of a die-attachment portion of a substrate that further includes an electrically conductive lead having an upper surface coplanar with the upper surface of the die-attachment portion;
transferring a mass of electrically conductive material onto the upper surface of the electrically conductive lead by use of Laser Induced Forward Transfer (LIFT) processing to form a gap-filling spacer; and
mounting a bottom surface of an electrically conductive flat clip onto the semiconductor integrated circuit die and the gap-filling spacer using a solder paste material;
wherein the semiconductor integrated circuit die is sandwiched between the die-attachment portion of the substrate and the electrically conductive clip;
wherein the electrically conductive flat clip has a distal portion extending away from the semiconductor integrated circuit die; and
wherein the gap-filling spacer substrate is sandwiched between the electrically conductive lead and the distal portion of the electrically conductive flat clip.

2. The method of claim 1 wherein the mass of electrically conductive material comprises a mass made of copper or silver.

3. The method of claim 1, wherein transferring comprises performing a plurality of transfers of masses of electrically conductive material using a corresponding plurality of LIFT processing steps.

4. The method of claim 1, wherein the bottom surface of the electrically conductive flat clip mounted onto the semiconductor integrated circuit die and the bottom surface of the electrically conductive flat clip mounted onto the gap-filling spacer are coplanar.

5. The method of claim 4, further comprising forming a notch in the electrically conductive flat clip between the bottom surface of the electrically conductive flat clip mounted onto the semiconductor integrated circuit die and the bottom surface of the electrically conductive flat clip mounted onto the gap-filling spacer.

6. The method of claim 5, wherein mounting comprises aligning the notch with an edge of the semiconductor integrated circuit die.

7. A device, comprising:
a semiconductor integrated circuit die attached to an upper surface of a die-attachment portion of a substrate that further includes an electrically conductive lead having an upper surface coplanar with the upper surface of the die-attachment portion;
a gap-filling spacer at the upper surface of the electrically conductive lead that is formed by transfer of a mass of electrically conductive material onto the upper surface of the electrically conductive lead by use of Laser Induced Forward Transfer (LIFT) processing; and
an electrically conductive flat clip having a bottom surface mounted onto the semiconductor integrated circuit die and the gap-filling spacer using a solder material;
wherein the semiconductor integrated circuit die is sandwiched between the die-attachment portion of the substrate and the electrically conductive flat clip;
wherein the electrically conductive clip has a distal portion extending away from the semiconductor integrated circuit die; and
wherein the gap-filling spacer substrate is sandwiched between the electrically conductive lead and the distal portion of the electrically conductive flat clip.

8. The device of claim 7, wherein the mass of electrically conductive material for the gap-filling material comprises copper or silver.

9. The device of claim 7, wherein the bottom surface of the electrically conductive flat clip mounted onto the semiconductor integrated circuit die and the bottom surface of the electrically conductive flat clip mounted onto the gap-filling spacer are coplanar.

10. The device of claim 9, wherein the electrically conductive flat clip includes a notch between the bottom surface of the electrically conductive flat clip mounted onto the semiconductor integrated circuit die and the bottom surface of the electrically conductive flat clip mounted onto the gap-filling spacer.

11. The device of claim 10, wherein the notch is aligned with an edge of the semiconductor integrated circuit die.

12. The device of claim 7, wherein the gap-filling spacer is formed by a plurality of transfers of masses of electrically conductive material using a corresponding plurality of LIFT processing steps.
